(19) United States
(12) Patent Application Publication
(10) Pub. No.: US 2015/0120218 A1
(43) Pub. Date: Apr. 30, 2015

(54) NOVEL METHOD FOR REAL TIME TESTS AND DIAGNOSIS OF PARTIAL DISCHARGE SOURCES IN HIGH VOLTAGE EQUIPMENT AND INSTALLATIONS, WHICH ARE IN SERVICE OR OUT OF SERVICE, AND PHYSICAL SYSTEM FOR THE PRACTICAL USE OF THE METHOD

(71) Applicants: Fernando Garnacho Vecino, Madrid (ES); Miguel Angel Sanchez-Uran Gonzalez, Madrid (ES); Javier Ortego La Moneda, Madrid (ES)

(72) Inventors: Fernando Garnacho Vecino, Madrid (ES); Miguel Angel Sanchez-Uran Gonzalez, Madrid (ES); Javier Ortego La Moneda, Madrid (ES)

(73) Assignee: UNIVERSIDAD POLITECNICA DE MADRID, Madrid (ES)

(21) Appl. No.: 13/701,451

(22) PCT Filed: May 24, 2011
(86) PCT No.: PCT/ES2011/000168

§ 371 Date: Feb. 7, 2013

(30) Foreign Application Priority Data
May 31, 2010 (ES) P201000713

(51) Int. Cl. G01R 31/02

(52) U.S. Cl. CPC G01R 31/024
USPC 702/58

(57) ABSTRACT

A method for detecting events associated with partial discharges (PDs) in high voltage equipment and installations diagnoses insulation conditions in real time by using PD signal noise discrimination by the parallel use of multiprocessors, which are additionally used for the discrimination, in real time, of different PD sources located in a single position or in different positions. In order to identify the various PD sources, three-dimensional clusters are formed using the coordinates of three parameters characteristic of each pulse: the parameter associated with the front time of the impulse, the parameter associated with the tail time and the parameter associated with the pulse frequency. The diagnostic method can be performed with grid voltage or independent generators as a voltage source, and the invention particularly relates to a novel voltage source designed therefor. A system for the implementation of the method captures PDs, and performs the necessary analysis and measurement.

### OBJECT OF THE INVENTION

The present invention relates to a new diagnostic method for diagnosis of partial discharges (PDs) which complements the methods and systems for the continuous monitoring of (PDs) permanently installed in high voltage equipment or installations and consuming longer calculation time periods for analysing the measurements. The new invention reduces the analysis time, which allows performing real time diagnoses of the insulation condition of high voltage equipment and installations. Additionally, the new invention allows performing the diagnosis either by using the high voltage power grid itself (measurements in service) or with a novel voltage source designed therefor (measurements out of service) as a voltage source. The term high voltage equipment must be understood as a voltage and/or alternating or direct current generator, power transformer, voltage and/or current measurement and/or protection transformer, control switchgear, insulators and surge arresters, and the term high voltage installation must be understood as: high voltage cable systems with their junction and termination accessories, gas-insulated transmission lines, gas-insulated sub-stations and a metal-enclosed high voltage switchgear assembly.

The new method proposed by the present invention improves the processing time of the measured signals and achieves identifying the different focal points of PDs existing in the measured installation. It additionally includes a novel system for generating a high test voltage suitable for applying the new method when the grid voltage is not used (measurements out of service).

### BACKGROUND AND SUMMARY OF THE INVENTION

The measurement of partial discharges has proven to be the most effective method for the diagnosis of the high voltage insulation equipment, machines and installations, such as measurement and protection transformers, switchgear, power transformers and reactors, alternators, gas-insulated sub-stations, cables with their installed accessories and gas-insulated lines.

A “partial discharge” must be understood in the context of this document as an electric discharge affecting a limited part of the insulation where it is produced, without causing its immediate failure, but its progressive degradation, except in the case of ambient air which is renewed naturally.

The practical difficulties in partial discharge measurements in equipment and installations proposed to be solved by the present invention are:
On one hand, the high calculation and analysis time consumption which powerful and complex numerical tools require for applying the mathematical algorithms for discriminating the interfering electric noise masking the electric PD signals due to defects in the high voltage insulation.
On the other hand, the difficulty in identifying and discriminating the total number of the PD sources for the purpose of separating them from one another and being able to identify each of them with the defect originating it.
And finally, the difficulty in generating high test voltages with alternating voltage waveforms of the same frequency as the grid service frequency (50 Hz or 60 Hz) without requiring large volume and heavy generators.

The current techniques applied for real time PD measurements performed in the field relate to solving some of these problems in a different manner, but with serious limitations, as explained below:

### a) Problems in Real Time Electric Background Noise Discrimination:

Most known methods treat the electric background noise problem by means of filtering the recorded signal in a frequency band in which the noise is presumably located. Filtering is sometimes performed for selective frequencies in a narrow frequency band.

It must be pointed out that the very conception of this filtering technique removes or attenuates the noise together with the PD signal for the filtered frequency range.

Another known method analyses the frequency spectrum of the noise signal for the purpose of choosing a measurement frequency band where the amplitude of the noise is the lowest possible amplitude. The drawback of this method is that sometimes the smallest noise signal band coincides with the band where the PD signal is also weak in amplitude, so PD measurement is difficult.

Another method which relates to removing noise by means of classifying the recorded signals (PDs+noise) into clusters is also known. The clusters are formed by means of determining parameters associated with the signal shape (duration and frequency) and its amplitude. The specific drawback of this method is that the processing is performed by signal level, such that to assure the capture of PD signals the acquisition level must be reduced, and therefore the noise signal content considerably increases. Processing becomes very laborious because the noise is put together with the PDs.

None of these methods is efficient for white noise, the spectrum of which covers all the frequencies of the PD signal. Frequency filtering techniques cannot be applied because the PD signal would also be lost, and a noiseless frequency band cannot be chosen either because there is a noise signal in all of them and PD clusters having a frequency different from that of the noise cannot be distinguished either.

An efficient technique for white noise is to apply the Wavelet transform of the recorded signal and statistically analysing its components in order to find transient events characteristic of PD pulses which are distinguished from the statistical evolution of the electric noise. The huge drawback of this technique for real time measurements is the high numerical processing time consumption of the recorded signals for discriminating noise from the PDs.

In the proposal of the new invention, noise is removed by applying the Wavelet transform to the recorded signal and statistically analysing its components for the purpose of finding events characteristic of PD pulses. The problem of the high processing time consumption required by this method is sought to be solved by means of multiple signal processing. High computing devices developed for personal computers, such as for example graphics cards having several multiprocessor units (GPGPU, General-Purpose Computing on Graphics Processing Units) allow drastically reducing calculation times, making the application of this powerful analysis technique to real time diagnostics viable.

b) Problem with Identifying and Discriminating Different PD Sources:

Most known methods relate to identifying and discriminating the total number of PD sources through locating PD pulses, for example for locating PDs in a cable, the theory of wave propagation through a cable is used, either by using the reflectometry technique or by using the technique of arrival time delays of one and the same PD signal to two or more sensors distributed along the length of the cable.

The efficacy of these methods for identifying and discriminating different PD sources is limited by the uncertainty in the location of the PD source, which can be a few metres, such that it is impossible to assure that there is only one PD source in a specific location (for example in a cable termination accessory), one PD source being able to mask others located nearby. This is particularly critical when the predominating PD source is associated with a danger-free phenomenon, such as for example corona in air, other PD sources co-existing close to it having a smaller amplitude but a higher risk of failure, such as defects inside the insulation for example.

Some techniques use the phase displacement of the PDs in relation to the applied voltage for identifying different PD sources. Characteristic phase resolved PD patterns in phase of the test voltage, which are referred to as reference PD patterns, are known to be produced as a function of the type of defect (cavity inside the insulation, surface discharge in dirty or faulty insulations, corona effect in air in sharp-pointed conductive parts, etc.). If the measured pattern is compared with the reference patterns, it is possible to observe whether there is a single defect or several defects. However, when there are several defects, their corresponding patterns can overlap and be easily confused with one another, without it being easy to identify each and every one of them, the operator's experience being crucial for a correct diagnosis. Additionally, the noise not removed in many commercial techniques makes the identification of different PD sources through the simple visual observation of their patterns of PDs even more difficult.

Another more advanced technique establishes PD clusters as a function of two shape parameters of each PD pulse: pulse duration and pulse oscillation frequency. However, the shape of the PD signal can be very different as a function of the rise time and fall time of the PD pulse envelope, even though the PD signal has the same total duration and the same oscillation frequency.

The proposal of the new invention relates to solving this problem by characterizing the shape of the PD pulse by means of three parameters instead of two: parameter correlated with the front time of the envelope of the pulse, parameter correlated with the fall time of the envelope of the pulse and parameter correlated with the pulse oscillation frequency. The degree of discrimination of different PD clusters, particularly when there are a number of pulses to be distinguished having a similar duration, is improved with this technique.

c) Problem with Generating High Test Voltages Having the Same Frequency as the Grid Voltage for PD Measurement in Large Installations:

Many generating systems used for testing large high voltage installations, such as for example cables several kilometres long, generate high test voltages with waveforms that are very different from the waveform of the service voltage in the power grid where the equipment operates (sinusoidal alternating voltage of 50 Hz or 60 Hz) for the purpose of not having to require a high power supply.

The first technique developed for on-site PD measurement tests was the very low frequency generator (0.1 Hz or 0.01 Hz). The low frequency of the generated voltage increases hundreds of times if it is 0.1 Hz, or thousands of times if it is 0.01 Hz, the capacitive reactance of the installation to be tested and, the power required during the test is thereby reduced in virtually the same proportion.

The drawback of this technique is that the generated alternating voltage wave duration is hundreds of times higher if it is 0.1 Hz or thousands of times higher if it is 0.01 Hz than the sinusoidal wave duration of 50 Hz or 60 Hz of the power grid where the high voltage equipment and installations operate. The voltage distribution inside insulations and the dielectric behaviour of insulations are known to be different for 0.1 Hz and 0.01 Hz voltages than for 50 Hz or 60 Hz voltages, so the tests do not reliably reflect the behaviour of the insulation when it is subjected to the grid voltage.

Damped alternating voltage generators generating high damped oscillating voltages having frequencies comprised between a tenth of a hertz and a kilohertz, which consist of charging the equipment or installation to be tested with a high direct voltage source and causing a damped oscillating voltage when discharging it on a coil, have emerged in recent years. The resistive value of the test circuit conductor causes the damping of the generated alternating voltage wave.

The limitation of this technique is that the maximum oscillating test voltage is applied only in the first crest of the voltage. The inevitable damping of the oscillating voltage wave provoked by the self-resistance of the actual circuit means that in the next wave half-periods have smaller amplitude and the wave is more considerably attenuated by a few tenths of a millisecond, causing less dielectric stress in the insulation. Dielectric stress, and therefore the result of the PD measurement in insulations, is known to depend not only on the instantaneous level of the test voltage, but also on the applied voltage duration. Therefore, UNE standard 60270 establishes the PD measurement in pC as the largest PD value occurring repeatedly throughout the test. For that purpose, the PD measurement instrument must be read as a function of the repetition rate of PD pulses per second, during which time the test voltage must remain constant without attenuation or damping.

Additionally, it is important to point out that the most common surge stresses in electric power transmission and distribution grids are due to single-phase short circuits causing surges in healthy phases during a time interval of the order of a few tenths of a second or even a second until the protections act. Accordingly, surges lasting a few hundredths of a second produced by the damped oscillating waves indicated in the preceding paragraph are not representative of the temporary surges of the grid.

The most advanced technical solution today for generating test voltages having the same frequency as the grid (50 Hz or 60 Hz) are fixed frequency LC resonant systems with variable inductance. The drawback of these systems is the required weight and volume.

Variable frequency LC resonant systems have also been developed having as advantages in relation to fixed frequency resonant systems a smaller generator weight (between half and five times less than the weight) and the higher compensated power ratio in relation to the active power required (between 1.2 to 2 times higher), but in contrast, the frequency is not exactly the grid frequency, but values comprised between 20 Hz and 300 Hz, which does not comply with the ideal target of testing insulations at the actual frequency of the grid where they operate (50 Hz or 60 Hz).

The proposal of the new invention seeks to solve this problem by compensating the reactive power by means of power electronics if the three phases are tested simultaneously by means of a FACT system. The weight and volume of the generator is also reduced by means of generating a high alternating voltage of 50 Hz during short time periods, of the order of a second, as if it were a temporary surge characteristic of a short circuit in the grid, then waiting a time interval to apply the test voltage again. A feasible example with current technology is to apply two seconds of test voltage for each real time minute, such that in 5 minutes a total of 500 wave periods of 50 Hz is provided, figure that is more than enough for the statistical treatment of the PD measurements which allows evaluating insulation condition. This method for testing, measuring and analysing allows requiring only maximum active power stresses in very isolated cases from the generator and thereby greatly reducing the weight and volume of the generator to values lower than those of the techniques used today.

### BRIEF DESCRIPTION OF THE DRAWING

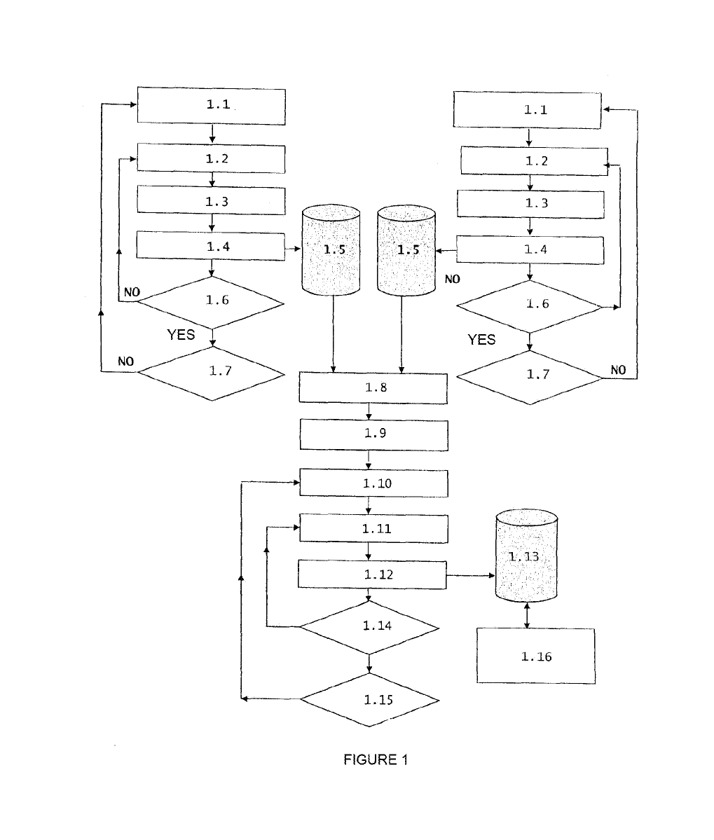

For the purpose of complementing the description and making the explanation thereof easier, FIG. 1 is attached for a non-limiting illustrative purpose, depicting a flow chart illustrating the method of the present invention;

### DESCRIPTION OF AN EMBODIMENT OF THE INVENTION

As mentioned above, the present invention consists of a method for measuring and analysing the measurement, for a real time evaluation of the insulation condition of high voltage cables during their operation in the grid or when they are not connected to the network, which improves the techniques used today and corrects the drawbacks associated with these techniques as stated.

The objective of the present invention is to provide a new method for measuring and analysing the measurement of partial discharges for the real time evaluation of the insulation condition of high voltage machines, apparatuses, equipment and installations such as insulated cables, either during their normal operation in the grid or out of service in the grid, by means of using a test generator specifically designed for applying the indicated new method for measuring and analysing.

The present invention allows reducing the time necessary for analysing the measurement, for the purpose of performing a real time diagnosis, by the parallel use of several computing multiprocessors developed for personal computers. The new method also allows discriminating different focal points or sources producing partial discharges, both those occurring in locations that are physically close to one another, for example in one and the same high voltage apparatus, machine or element, such as in a cable junction or termination, or those occurring far from one another in different apparatuses, machines or other parts of a high voltage installation.

To apply the method for measuring, it is necessary to use a PD measurement system and a high voltage measurement system, both referring to the same time basis. The PD measurement system will be formed by an electromagnetic sensor working in a frequency range comprised between 50 kHz and 20 MHz and a high speed sampling digital recording channel controlled by a personal computer.

The method for evaluating the insulation condition of installations having a certain length (greater than 20 m) requires two measurement and measurement analysis systems synchronised in time, for example through a GPS signal. Each PD measurement system is located in a different position of the high voltage installation, spaced from one another by at least 20 m. PD sensors integrated in each accessory or external sensors outside the high voltage equipment can be used for that purpose.

Additionally, when the PD measurement is taken in high voltage installations there can be short range PD sensors, such as very high frequency (VHF) sensors, ultra high frequency (UHF) sensors or acoustic sensors which only detect PDs produced close to the sensor (a few metres away from the sensor), so they must be placed in points where PDs are suspected to occur or in critical positions where the consequences of a failure would be disastrous. The comparison between the PD pulses acquired by these latter sensors located in a piece of equipment or accessory (for example a cable termination or junction) and the PD pulses detected by the electromagnetic sensors working between 20 kHZ and 20 MHz help to ratify the position of the PD sources.

This objective has been fully achieved with the present invention and is characterised by the attached claims in which the claimed method contemplates the stages that are described below and schematically shown in relation to the flow chart of FIG. 1 of the drawing. Therefore:

The method for measuring partial discharges requires the sequence of stages indicated below. When the PD measurements are applied to high voltage installations, such as insulated cables, the first six stages are also repeated in the two synchronised measurement systems. It is also possible to take a PD measurement in smaller, individual equipment, such as electric machines (generators and transformers), switchgear, measurement transformers, using a single measurement system being sufficient, in which case the seventh and eighths (blocks 1.7 and 1.8) are not applied.

A first stage of the method (block 1.1) consists of performing captures starting in the instant of exact seconds of the UTC (Universal Time Coordinated). This capture start signal is achieved, for example, from the PPS (pulse per second) signal of a GPS receiver in a fixed position and by means of the sensing of at least four satellites, it achieves errors of absolute time of less than 10 nanoseconds. The capture process collects, on one hand, the signal coming from the PD sensor; the signal measurement is also collected by the test voltage sensor, plus the grid voltage signal (in the event that the excitation is not the grid voltage). The part of the signal collected by the PD sensor that will be used corresponds to an integer “n” of test voltage periods (n for 20 ms for 50 Hz voltages). Where a period starts and ends is established by means of analysing the test voltage signal. The number “n” of periods of each capture depends on the available memory for storing data and on the need to update results on the observation screen. During the PD capture time period, the applied voltage must be the test voltage for the PD measurement. When the grid voltage signal, in addition to the test voltage signal, has been collected it enables performing the following steps in relation to any of the two reference signals.

The second stage (block 1.2) consists of segmenting the total capture interval into “n” complete time periods of the reference signal (having a duration of 20 ms for the 50 Hz reference signal) which will primarily be the test voltage, but it can possibly be the grid voltage when it is different from the test voltage for the purpose of performing the numerical analysis of the PD signal measurement relating to the separation of the electric noise and the calculation of parameters of the PD-type signals in the next stages 3 and 4 (blocks 1.3 and 1.4 respectively) for each of the individual periods.

The third stage (block 1.3) consists of the real time separation of the electric noise from the signal acquired by the PD sensor by use of multiprocessors. The electric noise is a mixture of signals coupled to the PD signals, either in a conducted manner through the power supply system or the grounding system, or transmitted in a broadcast manner, for example by radio stations, mobile telephones, etc.

The removal of the electric noise is performed by means of numerical treatment of the captured signals consisting of applying the Wavelet transform to the acquired signal and statistically analysing its components for the purpose of finding transient events characteristic of PD signals which are distinguished from the statistical evolution of the electric noise.

The processing time of the signal applied for the numerical treatment for removing noise is drastically reduced, sharing out the numerical calculation tasks between the available “m” multiprocessors of the GPGPU used for that purpose. The greater the process time reduction achieved, the higher the number of multiprocessors available, the higher the clock frequencies of the processors, the clock frequency of the memory and the communication bandwidth with the main memory. The time reduction ratio achieved allows easily processing each 20 ms period of the signal coming from the PD sensor in a time of 100 ms, which allows updating the results screen instantaneously for visual purposes.

In the fourth stage (block 1.4) the individual PD signals are processed for the purpose of determining the following parameters for each PD-type signal: the absolute arrival time tᵢ of the PD pulse in reference to the UTC time signal (for example GPS signal), the phase angle over time φᵢ in relation to the zero-crossing of the test voltage signal. When the test voltage is different from the grid voltage, the phase angle over time is also determined in relation to the zero-crossing of the grid voltage signal. The representation in relation to the grid signal allows differentiating PD events distant from the test voltage.

The parameters identifying the shape of the PD-type signal are also calculated. The current waveform corresponding to each PD-type signal, damped oscillating transient wave iᵢ(t), is modelled by means of a sinusoidal function gᵢ (first part of formula (1)), modulated by an function envelope eᵢ (second part of formula (1)), which is defined in this invention as the asymmetrical hyperbolic secant because it corresponds with the mathematical hyperbolic secant function in which the parameters of the two exponential functions of the denominator are no longer equal in order to lose the symmetry in relation to the y-axis (second part of the equation (1)).

$${i}_{i} ( t ) = {g}_{i} ( t ) \cdot {e}_{i} ( t ) = ( sine ( {ω}_{i} \cdot t - {ψ}_{i} ) ) \cdot ( \frac{{A}_{i}}{{e}^{{α}_{i} \cdot ( t - {t}_{0 i} )} + {e}^{{β}_{i} \cdot ( t - {t}_{0 i} )}} ) \qquad ( 1 )$$

### Where:

t is the time variable,
gᵢ(t) is the sinusoidal function associated with the i-th pulse having a frequency fᵢ=[(ωᵢ/2π] displaced ψi radians for the instant t=0,
ωᵢ pulse of the sinusoidal wave associated with the i-th pulse,
ψᵢ is the angular displacement of the sinusoidal wave associated with the i-th pulse for the time instant t=0,
ei is a function similar to the expression of the hyperbolic secant associated with the i-th pulse which, when the parameters αᵢ and βᵢ are different, asymmetry is achieved. This function modulates the amplitude Aᵢ of the sinusoidal function gᵢ.
t₀ᵢ is the temporal displacement of the asymmetrical hyperbolic secant modulating the i-th oscillation pulse.
Ai is the parameter directly correlated with the maximum amplitude of the envelope in combination with αᵢ and βᵢ.
αᵢ and βᵢ are the envelope shape parameters correlated to the front time and the tail time of the envelope wave.

Formula (1) has been obtained after an in-depth investigation of different mathematical models which best fit with the transient evolution of the damped oscillating pulse characteristic of a PD, with the parameters necessary for representing any type of PD signal and with a sensitivity of their parameters suitable for numerical calculation.

The best option of the six shape parameters t₀ᵢ, ψᵢ, fᵢ, Aᵢ, αᵢ and βᵢ for the “i-th” PD-type pulse is determined by means of a genetic search algorithm.

The use of multiple processors allows assigning to each processor the parameter search operations such that they better define each PD pulse. The parallel work of the “m” multiprocessors allows determining a broad set of genetic variations (around 4000) of each PD pulse for the purpose of choosing the best option for each of the PD pulses.

In the fifth stage (block 1.5), the best shape parameters determined for each PD-type pulse, are stored in the database of the computer controlling the measuring system.

Even though there are six shape parameters determined by means of the indicated numerical processing, the parameters that are independent of the instant which a PD is produced are the following three: pulse oscillation frequency, fᵢ, rising rate and falling rate of the PD pulse envelope (associated with the parameters αᵢ and βᵢ). The parameters t₀ᵢ and ψᵢ are parameters that can be attributed to displacements over time of the functions gᵢ(t) and eᵢ(t), and the parameter Aᵢ corresponds to a scaling factor.

In the sixth stage (block 1.6), the process of the third, fourth and fifth stages (blocks 1.3 a 1.5) is repeated until completing the acquired “n” periods.

In the seventh stage (block 1.7), the first stage (block 1.1) is repeated to enable again applying the stages comprised between the second and the sixth stages (blocks 1.2 to 1.6), until completing a statistically representative number of acquisitions so that the PDs can be immediately and reliably clustered by position, the PDs can be clustered in each position according to the shape of the pulse and the results of each PD source (magnitude, rate and phase resolved pattern of the voltage) can be determined, corresponding to the ninth, tenth and eleventh stages (blocks 1.9, 1.10 and 1.11 respectively). The number of acquisitions that is considered statistically minimum for reliably performing the mentioned analysis is 250, but the higher this number the more reliable the diagnosis will be.

The eighth stage (block 1.8) consists of representing the values of magnitude of the phase resolved discharge of the test voltage (φᵢ). When the grid voltage is different from the test voltage, the same values of the magnitude of the phase resolved discharge of the grid voltage (φᵣᵢ) are also represented. When the PDs are correlated to the phase of the grid voltage RIO, the representation of the magnitude of the phase resolved discharge of the test voltage (φᵣᵢ) will be distributed without any reference pattern; whereas the magnitude of the phase resolved discharges of the grid voltage will correspond to a reference pattern. This allows excluding PDs originating from the grid voltage and which are therefore not generated in the element under testing.

The ninth stage (block 1.9) consists of communicating both computers so that both databases containing PD pulse parameters obtained by both independent measurement systems can be correlated using the acquisitions synchronised in time by means of UTC, for example GPS.

In the tenth stage (block 1.10), the PD sources detected in different discrete positions throughout the installation are clustered together. Taking into account the data stored in the databases of the two measurement systems corresponding to the fifth stage (blocks 1.5), the position map of the PD sources is determined as a function of the position that the PD-type signals occupy along the length of the cable. The mentioned map is constructed as a function of the delay in arrival to each sensor of the PD pulses paired by proximity, xᵢ (Δₜᵢ), taking into account the maximum time delay possible between two PD pulses, the ratio between the maximum length to be travelled and the propagation speed.

“Position of PD pulses” must be understood as positions having a minimum length of about 3 m. The position is identified in relation to the relative distance to a specific sensor used as a reference.

The eleventh stage (block 1.11) consists of separating the PDs located in one and the same position, those having PD pulses with different shape parameters. It is known that the shape of the PD pulse (rise time, fall time, oscillation frequency) can change as a function of the physical phenomenon associated with a PD, of the distance travelled by the PD and of the test and measurement circuit. Accordingly, if there are different types of defects in a single position that produce PD-type signals, it will be possible to identify the different PD sources through the shape parameters associated with the PD pulses of each source generating PDs.

A three-dimensional representation of the most representative shape parameters of the pulses, fᵢ, αᵢ and βₗ, is made to enable applying this step, and a clustering tool is applied for determining the different focal points associated with different sets of discharges in said three-dimensional space.

The twelfth stage (block 1.12) consists of determining the measurement and analysis results for each PD source: magnitude of the PD, rate of repetition of the PD and pattern of the phase resolved PDs for the voltage. The magnitude of the PD pulses and the rate of repetition of PD signals are determined for each PD source as mean values of each acquisition second. These two pieces of data are determined by statistical analysis of the set of PDs located in the each position where PDs occur:

The magnitude of the partial discharge is determined as the largest magnitude repeatedly occurring in each of the sensors, which is calculated through the quasi-peak value of the amplitudes of the PD signals recorded per each second of signal captured. The amplitude of each PD pulse sensed by each sensor is corrected as a function of the length travelled.

The rate of repetition is determined as the mean value of the PD-type signals of a certain level detected in a time period at least throughout an acquisition second.

The risk of insulation failure is known to depend on the physical process causing the PD pulses, e.g., corona in air pulses are not crucial for causing the dielectric breakdown of the insulation, but partial discharges due to an internal cavity-type defect are critical for the insulation service life. It is therefore very important to know the type of defect associated with each PD source to enable evaluating the insulation condition of a cable and of its accessories (terminals and junctions). The representation of the magnitude of the discharge in relation to the phase with reference to the test voltage (φᵢ) of the pulses of each PD source generates visual patterns which experience has proven to be highly correlated to the different types of phenomena causing the occurrence PD events. The recognition of the formed pattern allows evaluating the risk of failure of each of the PD sources. A neural network for pattern recognition is applied to each of the PD sources detected for automatic recognition, the training of which network has been conducted based on the patterns offered by laboratory samples and field tests through which the type of defect is known with certainty.

In the thirteenth stage the measurement and analysis results for each PD source (magnitude, rate of repetition and phase resolved pattern of the voltage) are stored in a database (block 1.13).

In the fourteenth stage (block 1.14), the eleventh to the thirteenth stages (blocks 1.11 to 1.13) are repeated for each PD source located in a specific position, and in stage fifteenth (block 1.15) the preceding process is again repeated for each set of PDs located in the different positions of the cable.

A user interface (block 1.16), schematically shown in FIG. 1, allows showing the processed data for performing the final evaluation of the insulation condition of the cable from the following information:
Position map of the PDs where the PD sources are located (block 1.10).
Clusters of different PD sources in each position (block 1.11).
Results obtained from each PD source as a function of time: magnitude, rate of repetition, phase resolved pattern of the voltage for each PD source (block 1.12).
Type of defect associated with each source obtained from the neural network (block 1.12).

The new method for monitoring partial discharges in cables that are installed and in service for discriminating, locating, measuring, identifying and diagnosing partial discharge sources has been sufficiently described above. Additionally, another object of the invention is the implementation of a system for carrying out said method, which will be described below.

According to the invention, the physical system for applying the proposed method is made up of one or two sub-systems for measuring and analysing the measurement of partial discharges and a sub-system for generating high alternating 50 Hz voltage particularly designed and suited to the mentioned method for measuring when the PD measurements must be performed without the grid voltage (out of service). In the event that the measurements are taken under service conditions or when they are taken under out of service conditions, the diagnosis of the insulation condition is done in the same manner in brief time periods. PD measurement sub-systems for applying the method.

For the complete application of the method for measuring and analysing described in the flow chart of FIG. 1 it is necessary to use two measurement systems, MS, for measuring each of the PD signals located at opposing ends of the installation to be tested. The MS include a PD measurement sensor, a measurement sensor for measuring the waveform of the test high voltage, a measurement sensor for measuring the waveform of the high voltage of the grid, a digital recorder, a UTC receiver, for example GPS, a personal computer with multiple processing capacity and a portable computer for remote control for the purpose of isolating the operator.

The PD-type signals together with the electric background noise present are captured and recorded by the measurement system (MS) in a synchronised manner through the UTC time reference (block 1.1 of the flow chart of FIG. 1). Each MS performs the processing of the collected signals:
It segments the capture time into periods to perform the analysis (block 1.2),
discriminates the electric background noise from the PD-type signals (block 1.3),
determines the parameters representative of each PD pulse (block 1.4) and stores them (block 1.5),
repeats the process until completing the capture period (blocks 1.6 and 1.7),
the PDs originated by the grid voltage far from the element under testing are excluded (block 1.8).

After the capture and the first processing of signals performed separately by each measurement system (blocks 1.1 to 1.8), both measurement systems are interconnected, with or without a cable, to transfer the data to one of them from the other. Any of the two computers has the necessary calculation tools for completing the processing of the analysis of the measurement and obtaining the final results of the evaluation of the insulation condition (blocks 1.10 to 1.17) for the purpose of displaying said results on the screen of the computer used (block 1.17 of the flow chart of FIG. 1).

Each measurement system, MS, arranged in the installation under testing is made up of:
one Partial Discharge Sensor per phase to be analyzed, PDS. The non-invasive sensors used are high frequency current transformers (HFCT) having a bandwidth comprised between 1 MHz and 20 MHz which are arranged coupled to the conductors of the connections to ground. The invasive sensors are integrated in equipment or elements of the installation,
one Test Voltage Sensor, TVS, for measuring the waveform of the test voltage. In the event of measurements in service, an output of a measurement and protection transformer of the actual grid, or a sensor capacitively coupled to the phase where the measurement is taken, can be used. A 50 Hz current transformer arranged in a ground connection of the high voltage cables can also alternatively be used. In this latter case, the electric phase difference of the measured capacitive current signal must be delayed 90° in relation to the voltage wave object of measurement. If the measurement is taken when out of service, the signal will be obtained from the low voltage branch of a voltage divider by means of a high alternating voltage generator,
a Grid Voltage Sensor, GVS, for measuring the grid voltage waveform in the event that it is different from the test voltage. An output of a measurement and protection transformer of the actual network, or a 50 Hz current transformer arranged in the conductor of the ground connection of the high voltage cables not forming part of the test and connected to the grid voltage can be used. In this latter case, the electric phase difference of the mainly capacitive current signal must be delayed 90° in relation to the voltage wave object of measurement,
a card for receiving the UTC time signal, for example a GPS card which is synchronised with the UTC time by means of the PPS (Pulse Per Second) signal, allowing the synchronised Trigger Pulse Generation (TPG),
a Digital Recording, DR, Card triggered by the synchronisation pulse coming from the TPG. The PDS is connected to a channel of the DR, the sampling speed and vertical resolution of which is at least 100 Mega-samples per second and 10 bits, respectively. The channel intended for the voltage waveform could have much less demanding features (32 kilo-samples per second).
Protection and Control Equipment, PCE, protecting the two DRs of the MS against surges,
a personal computer with multiple processing capacity through one or several multiprocessing units.
a portable computer for controlling the measurement system remotely.
   Sub-system for generating a high alternating voltage of 50 Hz applied to the new method for the measurement and analysis of PDs.

The system for generating a high alternating voltage of 50 Hz of the present invention subjects the equipment or installation to be tested to the test voltage only for short time periods in which the PD signals are captured (block 1.1 of the flow chart of FIG. 1). After each time interval for generating the high test voltage, the output voltage of the generator is reduced to a low enough value so that the power dissipated by the generator is negligible (waiting state), and the heat generated in the prior operation condition can be dissipated. The ratio, r, between the waiting time interval in relation to the time period for generating the high test voltage is established with a specific ratio compatible with the technology of the high voltage transformer used, for example, a maximum ratio of 5:1 could reasonably correspond to 10 seconds of high voltage generated with 50 seconds of waiting state per each time minute, so that the equivalent thermal load in the operation steady state is much lower than that required when operating at the test voltage.

In each test period tₜ in which the high test voltage is generated, the test current, Iₜ required by the equipment or installation to be tested, is supplied by the generator causing a thermal load. The current Iₑ during the waiting period tₑ is reduced to a percentage p in relation to the current during the test. The comparison between the thermal load in this pulsed state in relation to the thermal load in continuous operating steady state of a permanent nominal current generator Iₚ meets the following equation:

Iₗ²·tₗ+Iₑ²·tₑ=Iₚ²tₚ (2)

Where it results that

$${I}_{p} = {I}_{t} \cdot \sqrt{\frac{l + r \cdot p}{l + r}}$$

By way of example, if the ratio r=tₑ/tₜ=5 and the percentage of current in waiting condition is 25% in relation to the test current (p=0.25), it results that with one generator of the steady state nominal power having half the value of that required at the test voltage would be sufficient under the thermal load viewpoint.

By way of example, a test installation having a steady state nominal power of 250 kVA can be used in the indicated pulsed state (r=5 and p=0.25) to supply test powers of up to 500 kVA, without being heated above the nominal value.

During the period of generating high voltage, for example 10 seconds in a minute, at least, one time interval (for example 2 seconds), the high PD measurement voltage will be reached so that immediately during the waiting operation period of the generator, for example 50 seconds, the measurement system has enough time to perform the numerical processing of the signals, corresponding to filtering and determining the parameters representative of each PD-type pulse (blocks 1.2 to 1.6 of the flow chart of FIG. 1). The high test voltage will then be generated again to perform a new capture, and the process will be repeated as many times necessary (blocks 1.6 and 1.1 of the flow chart of FIG. 1). The number of times that the capture and analysis process is repeated must be enough so as to provide statistically reliable data. It is known that with a number of captures corresponding to 250 periods of the test voltage wave (for example 20 ms for 50 Hz) sufficient data is available for reliably performing the analysis corresponding to the tenth, eleventh and twelfth stages of the flow chart of FIG. 1. The higher the number of periods captured the more reliable the diagnosis will be.

By way of example, if in the time interval for generating a high voltage the time period reached by the test voltage intended for the PD capture and measurement is of the order of 2 seconds per each time minute and the process is repeated five consecutive times (5 minutes of testing), then twice the amount of test sinusoidal wave periods established as necessary (500 periods of data) will be available for performing the diagnosis of the insulation condition of the equipment or of the installation. Accordingly, in 5 minutes of testing it is possible to perform a reliable diagnosis with a voltage having the same frequency as the grid.

Additionally, considering that the duration of the test does not require exceeding a tenth of minutes and that no other test will be performed until after an hour has elapsed, the nominal power of the generator in steady state in relation to the maximum power delivered can be further reduced. The use of step-up transformers having lower power provides the fundamental advantage of a considerable weight reduction.

For the purpose of not having to supply more than the active power of losses, the reactive power required during the test is compensated by means of FACT-type power electronics, the weight of which is also reduced. Vector control of the FACT is performed with a reduced number of switching pulses to limit the interfering signal content during partial discharge measurement due to the switching of the electronic power switches at the same time of complying with the condition that the difference between the effective value of the generated voltage and the crest value divided by the square root of 2 does not exceed 15%. The combined use of a three-phase step-up power transformer and three-phase FACT for testing balanced tri-phase loads allows substantially reducing the use of traditional reactive compensation elements (reactors and condensers), the weight and volume of which have traditionally been a serious drawback. Additionally, the simultaneous test of the three phases provides the substantial advantage of reducing the test time.

The circuit of the test generation system is made up of the following elements:
a low voltage automatic switch for the connection, disconnection and protection,
a autotransformer that is adjustable by means of monitoring low voltage, provided for providing the active power required in the test,
a servomotor to adjust the output voltage of the autotransformer controlled by a computer for the purpose of coordinating the time periods in which the high test voltages are generated with the waiting periods, used for capturing, recording and analysing the signals coming from the PD sensors,
a three-phase FACT for compensating the reactive power required in the test,
a three-phase power transformer to increase the voltage from a low voltage to the test voltage.

1.-8. (canceled)

9. A method for identifying different clusters of partial discharges comprising for a plurality of electric signals sensed by a partial discharge sensor:
determining for the i-th electric signal the parameters of the damped oscillating event mathematical model eᵢ(t)*gᵢ(t), taking the mathematical function derived from the hyperbolic secant, eᵢ(t), containing the parameters αᵢ and βᵢ making it asymmetrical as a first factor of said model
$${e}_{i} ( t ) = \frac{{A}_{i}}{{e}^{{α}_{i} \cdot ( t - {t}_{0 i} )} + {e}^{- {β}_{i} \cdot ( t - {t}_{0 i} )}}$$
together with the parameters of the sinusoidal mathematical function, gᵢ(t), as a second factor of the oscillating event mathematical model
gᵢ(t)=sine(ωᵢ·t−ψᵢ)
which fit with the sensed electric partial discharge signal; extracting from the second factor the fundamental frequency fᵢ=ωᵢ/2π as the third representative parameter,
associating the i-th electric signal with a cluster of partial discharges according to the parameters fᵢ, αᵢ and βᵢ of the mathematical model.

10. The method according to claim 9, further comprising generating a high test voltage for measurements out of service of the same frequency as the grid service voltage.

11. The method according to claim 9, further comprising filtering the background electric noise in the captured electric signal.

12. The method according to claim 11, wherein the filtering of the background electric noise comprises applying the Wavelet transform.

13. The method according to claim 9, further comprising locating the position of the source of partial discharge according to the synchronised measurement and absolute time difference in the acquired signal.

14. A system for identifying different clusters of partial discharges comprising for a plurality of electric signals sensed by a partial discharge sensor:
means for determining for the i-th electric signal the parameters of the damped oscillating event mathematical model eᵢ(t)*gᵢ(t), taking the mathematical function derived from the hyperbolic secant, eᵢ(t), containing the parameters αᵢ and βᵢ making the function asymmetrical as a first factor of said model
$${e}_{i} ( t ) = \frac{{A}_{i}}{{e}^{{α}_{i} \cdot ( t - {t}_{0 i} )} + {e}^{- {β}_{i} \cdot ( t - {t}_{0 i} )}}$$
together with the parameters of the sinusoidal mathematical function, gᵢ(t), as a second factor of the oscillating event mathematical model
gᵢ(t)=sine(ωᵢ·t−ψᵢ)
which fit with the sensed electric partial discharge signal; extracting from the second factor a fundamental frequency fᵢ=ωᵢ/2π as a third representative parameter,
means for the i-th electric signal with a cluster of partial discharges according to the parameters fᵢ, αᵢ and βᵢ of the mathematical model.

15. The system according to claim 14, further comprising means for generating a high test voltage for measurements out of service of the same frequency as the grid service voltage.

16. The system according to claim 14, further comprising a filter configured for filtering a background electric noise in the captured electric signal.

17. The system according to claim 16, wherein the filtering of the background electric noise comprises applying the Wavelet transform.

18. The system according to claim 14, further comprising means for locating the position of the source of partial discharge according to synchronised measurement and absolute time difference in the acquired signal.

19. The system according to claim 12, wherein comprising the following elements:
a partial discharge sensor;
a voltage sensor for measuring the waveform of the test voltage;
a card for receiving the UTC time signal, for example from a GPS system, and another card for synchronised trigger pulse generation (TPG)
a digital recorder triggered by the synchronisation pulse coming from the synchronised trigger pulse card;
protection and control equipment, protecting the two digital recorders of the measurement system against surges;
a personal computer with multiple processing capacity through one or several multiprocessing units;
a portable computer for remotely controlling the measurement system.
